(19) United States
(12) Patent Application Publication
(10) Pub. No.: US 2022/0336942 A1
(43) Pub. Date: Oct. 20, 2022

(54) ANTENNA SYSTEM, AND METHOD OF FORMING THE SAME

(71) Applicant: Agency for Science, Technology and Research, Singapore (SG)

(72) Inventor: Teck Guan LIM, Singapore (SG)

(21) Appl. No.: 17/639,478

(22) PCT Filed: Sep. 4, 2019
(86) PCT No.: PCT/SG2019/050442

§ 371 Date: Mar. 1, 2022

(51) Int. Cl. H01Q 1/22; H05K 1/02; H01Q 9/04

(52) U.S. Cl. CPC H01Q 1/2283; H05K 1/0243; H01Q 9/0407; H05K 2201/10098; H01L 23/3128

(57) ABSTRACT

Various embodiments may provide an antenna system. The antenna system may include a printed circuit board including a circuit board ground element. The antenna system may also include a package over a surface of the printed circuit board. The antenna system may further include a radiating element parallel to the surface of the printed circuit board. The package may include a first encapsulation portion, and a radio frequency integrated circuit chip embedded in the first encapsulation portion, the radio frequency integrated circuit chip parallel to the surface of the printed circuit board. The package may additionally include a package ground element over the first encapsulation portion and in electrical connection with the circuit board ground element, the package ground element parallel to the surface of the printed circuit board, and a second encapsulation portion between the package ground element and the radiating element.

### TECHNICAL FIELD

Various aspects of this disclosure relate to an antenna system. Various aspects of this disclosure relate to a method of forming an antenna system.

### BACKGROUND

Antenna in Package (AiP) is the integration of the antenna circuit in a radio frequency integrated circuit (RFIC) package. However, it suffers from low gain due to the limited package footprint which reduces the aperture size. Although the size of the antenna reduces when the frequency increases, the antenna size is still significant. Usually, the antenna performances have to be compromised.

FIG. 1 is a schematic showing a cross-sectional view of a conventional antenna system 100. FIG. 1 shows an Antenna in Package (AiP) 100 including a patch over a printed circuit board. In this design, the ground plane of the patch antenna is formed in the package 100. As a sufficient large ground plane is required to achieve good radiating performance, the package size becomes large. This make the AiP not cost effective, especially for the fan-out wafer level package (FOWLP) technology.

### SUMMARY

Various embodiments may provide an antenna system. The antenna system may include a printed circuit board (PCB) including a circuit board ground element. The antenna system may also include a package over a surface of the printed circuit board. The antenna system may further include a radiating element lying along a first plane parallel to the surface of the printed circuit board. The package may include a first encapsulation portion. The package may also include a radio frequency integrated circuit chip embedded in the first encapsulation portion, the radio frequency integrated circuit chip lying along a second plane parallel to the surface of the printed circuit board. The package may additionally include a package ground element over the first encapsulation portion and in electrical connection with the circuit board ground element, the package ground element lying along a third plane parallel to the surface of the printed circuit board. The package may also include a second encapsulation portion such that the second encapsulation portion is between the package ground element and the radiating element.

Various embodiments may relate to a method of forming an antenna system. The method may also include forming a package over a surface of a printed circuit board, the printed circuit board including a circuit board ground element. The method may further include forming a radiating element lying along a first plane parallel to the surface of the printed circuit board. The package may include a first encapsulation portion. The package may also include a radio frequency integrated circuit chip embedded in the first encapsulation portion, the radio frequency integrated circuit chip lying along a second plane parallel to the surface of the printed circuit board. The package may additionally include a package ground element over the first encapsulation portion and in electrical connection with the circuit board ground element, the package ground element lying along a third plane parallel to the surface of the printed circuit board. The package may further include a second encapsulation portion such that the second encapsulation portion is between the package ground element and the radiating element. An area of the radiating element along the first plane may be greater than an area of the package ground element along the third plane. The area of the radiating element along the first plane may be also greater than an area of the radio frequency chip along the second plane. The third plane may be between the first plane and the second plane.

### BRIEF DESCRIPTION OF THE DRAWINGS

The invention will be better understood with reference to the detailed description when considered in conjunction with the non-limiting examples and the accompanying drawings, in which:

FIG. 1 is a schematic showing a cross-sectional view of a conventional antenna system.

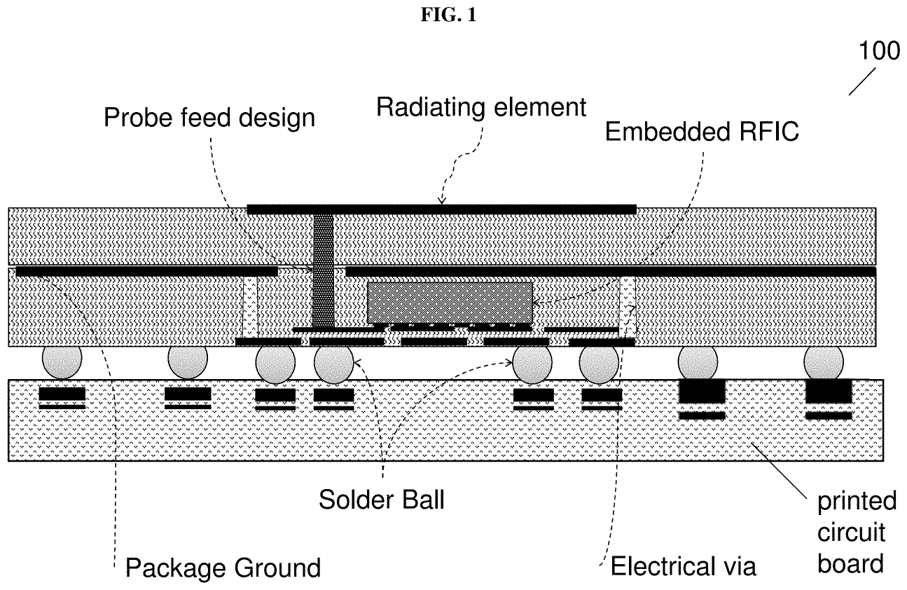

FIG. 2 is a general illustration of an antenna system according to various embodiments.

FIG. 3 is a schematic illustrating a method of forming an antenna system according to various embodiments.

FIG. 4A is a schematic showing a cross-sectional view of an antenna system according to various embodiments.

FIG. 4B is a schematic showing a three-dimensional perspective view of a simulated model of the antenna system shown in FIG. 4A according to various embodiments.

FIG. 4C is a schematic showing a cross-sectional side view of the simulated model of the antenna system shown in FIG. 4A according to various embodiments.

FIG. 5A is a plot of peak gain (in decibels or dB) as a function of frequency (in gigahertz or GHz) illustrating the effects of varying the size of the printed circuit board (PCB) ground on the antenna gain according to various embodiments.

FIG. 5B is a plot of peak gain (in decibels or dB) as a function of frequency (in gigahertz or GHz) illustrating the effects of varying the height of the solder balls on the antenna gain according to various embodiments.

FIG. 5C is a schematic showing a three-dimensional perspective view of a simulated model of a conventional antenna system.

FIG. 5D is a plot of peak gain (in decibels or dB) as a function of frequency (in gigahertz or GHz) illustrating the antenna gain of the conventional antenna system as shown in FIG. 5C.

FIG. 6A is a schematic showing a three-dimensional perspective view of an antenna array including two packages and two radiating elements over a common printed circuit board (PCB) according to various embodiments.

FIG. 6B is a schematic showing a cross-sectional side view of the antenna array shown in FIG. 6A according to various embodiments.

FIG. 7 is a plot of peak gain (in decibels or dB) as a function of frequency (in gigahertz or GHz) showing the electrical performance of the antenna array shown in FIGS. 6A-B according to various embodiments.

FIG. 8 is a schematic showing a cross-sectional view of an antenna system according to various embodiments.

FIG. 9 is a schematic showing a cross-sectional view of an antenna system according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or antenna systems are analogously valid for the other methods or antenna systems. Similarly, embodiments described in the context of a method are analogously valid for an antenna system, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

In order to improve the antenna performance without increasing the package size of the antenna ground plane is designed at the printed circuit board (PCB) ground instead.

Various embodiments may be applied to all types of antennas which require a large ground plane. In addition, various types of antenna feeds can be used for the design. A rectangular patch antenna with coaxial feed according to various embodiments is shown herein.

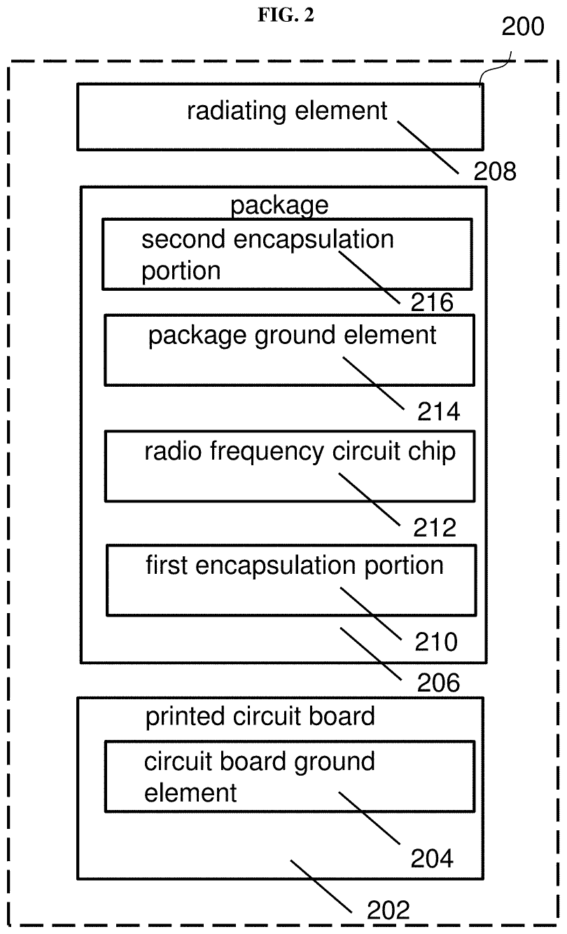

FIG. 2 is a general illustration of an antenna system 200 according to various embodiments. The antenna system 200 may include a printed circuit board (PCB) 202 including a circuit board ground element 204. The antenna system 200 may also include a package 206 over a surface of the printed circuit board 202. The antenna system 200 may further include a radiating element 208 lying along a first plane parallel to the surface of the printed circuit board 202. The package 206 may include a first encapsulation portion 210. The package 206 may also include a radio frequency integrated circuit chip 212 embedded in the first encapsulation portion 210, the radio frequency integrated circuit chip 212 lying along a second plane parallel to the surface of the printed circuit board 202. The package 206 may additionally include a package ground element 214 over the first encapsulation portion 210 and in electrical connection with the circuit board ground element 204, the package ground element 214 lying along a third plane parallel to the surface of the printed circuit board 202. The package 206 may also include a second encapsulation portion 216 such that the second encapsulation portion is between the package ground element 204 and the radiating element 208.

In other words, the antenna system 200 may include a printed circuit board (PCB) 202, a package 206, and a radiating element 208 which may be part of the package 206 in various embodiments, and which may not be part of the package 206 in various other embodiments. The printed circuit board 202 may include a circuit board ground element 204. The package 206 may include a first encapsulation portion 210, a radio frequency circuit chip 212, a package ground element 214, and a second encapsulation portion 216.

For avoidance of doubt, FIG. 2 serves to illustrate the features of an antenna system according to various embodiments, and is not intended to indicate or limit the shape, the size, the or

In various embodiments, the radiating element 208 may be configured to emit radio frequency signals in a direction away from the printed circuit board 202.

The printed circuit board 202 may have the surface which is facing the package 206 and the radio frequency circuit chip 212, as well as a further surface opposing the surface, the further surface facing away from the package 206 and the chip 212. In various embodiments, the package may be mounted to the surface of the printed circuit board 202. The circuit board ground element 204 may extend from the surface of the printed circuit board 202. The circuit board ground element 204 may lie on the surface of the printed circuit board 202. In various embodiments, at least a portion of the circuit board ground element 204 may be exposed on the surface of the printed circuit board 202.

In various embodiments, the radio frequency integrated circuit chip 212 may have an active surface facing the printed circuit board 202.

In various embodiments, the package 206 may be devoid of circuits in a space extending from the radiating element to the printed circuit board 202.

In various embodiments, the first encapsulation portion may include a mold compound. The second encapsulation may also include the mold compound. In various other embodiments, the first encapsulation portion may include a first mold compound, while the second encapsulation portion may include a second mold compound different from the first mold compound.

In yet various other embodiments, the first encapsulation portion 210 may include a mold compound, while the second encapsulation portion 216 may include a thermal conductive material, such as glass.

In various embodiments, the radiating element 208 may be included in the package 206.

In various embodiments, the radiating element 208 may not be part of the package 206.

In various embodiments, the radiating element 208 may extend beyond the package 206. The radiating element 208 may include a plurality of fins.

The package 206 may further include one or more signal electrical vias electrically connecting the radiating element 208 and the radio frequency integrated circuit chip 212.

In various embodiments, the package 206 may also include one or more ground electrical vias electrically connecting the circuit board ground element 204 and the package ground element 214.

The one or more ground electrical vias may surround the radio frequency integrated circuit chip 212.

In various embodiments, the package 206 may include a circuit board signal element in electrical connection with the radio frequency integrated circuit chip 212.

The antenna system 200 may also be referred to as a radiating module. The package 206 may be referred to as an Antenna in Package (AiP). The first encapsulation portion 210 may be a region or a layer. The second encapsulation portion 216 may be a region or a layer.

In various embodiments, the antenna system 200 may be an antenna array. The antenna system 200 may further include a further package over the surface of the printed circuit board. The printed circuit board may be common to the package 206 and the further package. The antenna system 200 may also include a further radiating element lying along the first plane parallel to the surface of the printed circuit board.

The further package may include a further first encapsulation portion. The further package may also include a further radio frequency integrated circuit chip embedded in the further first encapsulation portion, the further radio frequency integrated circuit chip lying along the second plane parallel to the surface of the printed circuit board. The further package may further include a further package ground element over the further first encapsulation portion and in electrical connection with the circuit board ground element, the further package ground element lying along the third plane parallel to the surface of the printed circuit board. The further package may also include a further second encapsulation portion such that the further second encapsulation portion is between the further package ground element and the further radiating element. An area of the further radiating element along the first plane may be greater than an area of the further package ground element along the third plane. The area of the further radiating element along the first plane may also be greater than an area of the further radio frequency chip along the second plane.

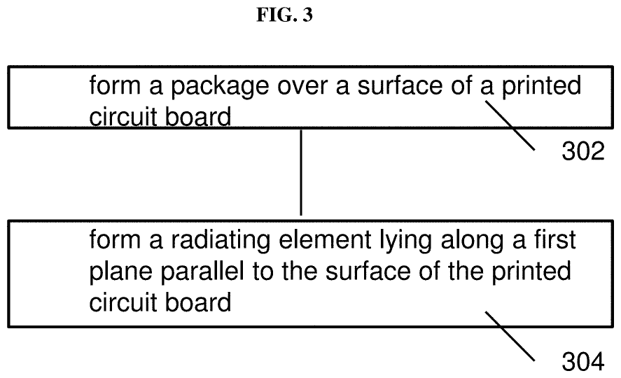

FIG. 3 is a schematic illustrating a method of forming an antenna system according to various embodiments. The method may also include, in 302, forming a package over a surface of a printed circuit board, the printed circuit board including a circuit board ground element. The method may further include, in 304, forming a radiating element lying along a first plane parallel to the surface of the printed circuit board. The package may include a first encapsulation portion. The package may also include a radio frequency integrated circuit chip embedded in the first encapsulation portion, the radio frequency integrated circuit chip lying along a second plane parallel to the surface of the printed circuit board. The package may additionally include a package ground element over the first encapsulation portion and in electrical connection with the circuit board ground element, the package ground element lying along a third plane parallel to the surface of the printed circuit board. The package may further include a second encapsulation portion such that the second encapsulation portion is between the package ground element and the radiating element. An area of the radiating element along the first plane may be greater than an area of the package ground element along the third plane. The area of the radiating element along the first plane may be also greater than an area of the radio frequency chip along the second plane. The third plane may be between the first plane and the second plane.

In other words, the method may include forming a package and a radiating element over a printed circuit board. The radiating element may be part of the package according to various embodiments, and may not be part of the package according to various other embodiments. The package may include a first encapsulation portion. The package may also include a radio frequency integrated circuit chip embedded in the first encapsulation portion, a package ground element, and a second encapsulation portion.

For avoidance of doubt, FIG. 3 serves to highlight the steps of a method of forming an antenna according to various embodiments. FIG. 3 is not intended to limit the sequence of the steps. For instance, step 302 may occur before, after, or at the same time as step 304.

In various embodiments, the radiating element may be configured to emit radio frequency signals in a direction away from the printed circuit board.

In various embodiments, the package may be mounted to the surface of the printed circuit board. The circuit board ground element may extend from the surface of the printed circuit board. The method may include forming or providing the printed circuit board.

In various embodiments, the radio frequency integrated circuit chip may have an active surface facing the printed circuit board.

In various embodiments, the package may be devoid of circuits in a space extending from the radiating element to the printed circuit board.

In various embodiments, the first encapsulation portion includes a mold compound. The second encapsulation portion may also include the mold compound.

In various other embodiments, the first encapsulation portion may include a mold compound. The second encapsulation portion may include a thermal conductive material, such as glass.

The method may include forming the first encapsulation portion. The method may include providing or forming the radio frequency integrated circuit chip. The method may also include forming the package ground element. The method may additionally include forming the second encapsulation portion.

In various embodiments, the radiating element may be included in the package. In various other embodiments, the radiating element may not be part of the package. The radiating element may extend beyond the package. The radiating element may include a plurality of fins.

In various embodiments, the package may further include one or more signal electrical vias electrically connecting the radiating element and the radio frequency integrated circuit chip. The method may further include forming the one or more signal electrical vias.

In various embodiments, the package may also include one or more ground electrical vias electrically connecting the circuit board ground element and the package ground element. The method may also include forming the one or more ground electrical vias. The one or more ground electrical vias may surround the radio frequency integrated circuit chip.

In various embodiments, the printed circuit board may further include a circuit board signal element in electrical connection with the radio frequency integrated circuit chip. The method may include forming the circuit board signal element.

In various embodiments, the method may also include forming a further package over the surface of the printed circuit board. The printed circuit board may be common to the package and the further package. The method may further include forming a further radiating element lying along the first plane parallel to the surface of the printed circuit board.

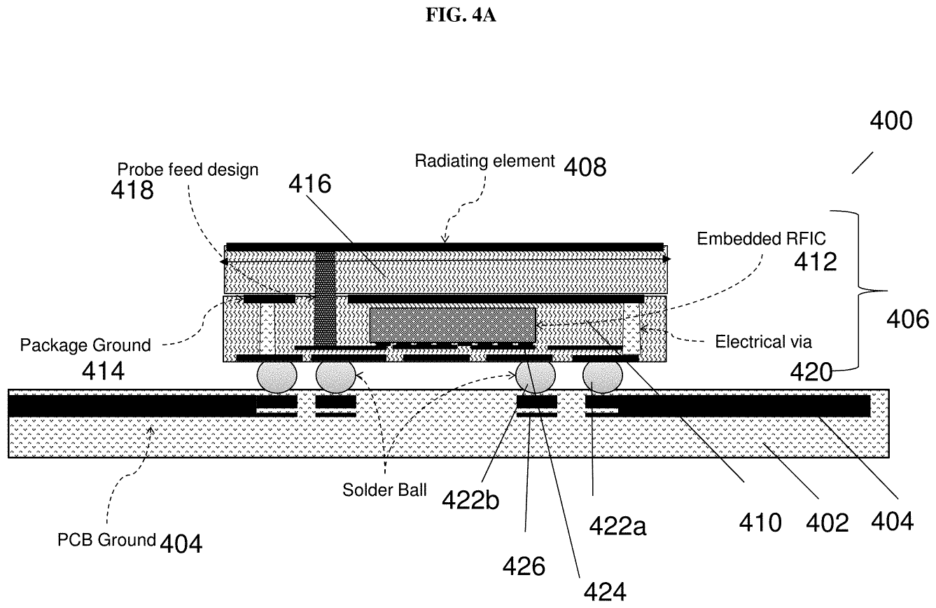

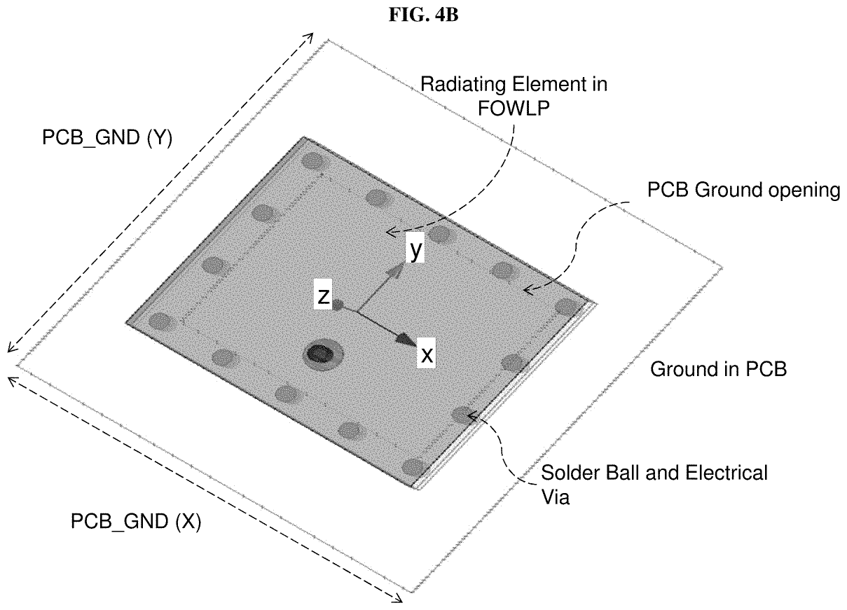

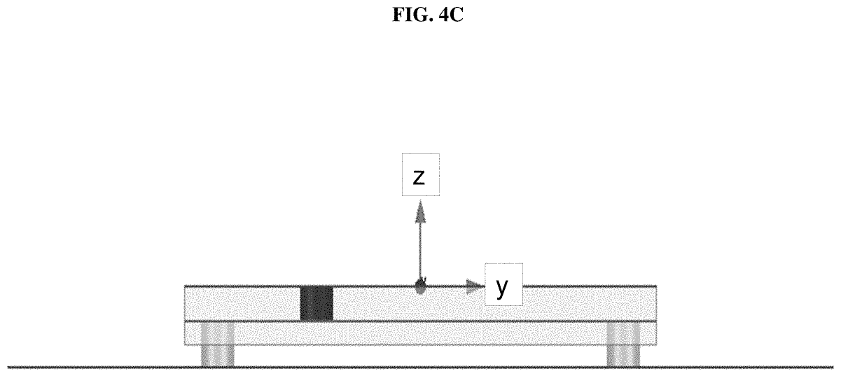

FIG. 4A is a schematic showing a cross-sectional view of an antenna system 400 according to various embodiments. The antenna system 400 may be referred to as a radiating module, and may be fabricated using Embedded Mold Compound (EMC) to form encapsulation portions, regions or layers 410, 416 using fan-out wafer level packaging (FOWLP) technology. The EMC for these 2 layers 410, 416 may be made of different materials such that they are optimised for the electrical, mechanical and thermal performances. In other words, the material included in layer 410 may be different from the material included in layer 416.

The hybrid AiP 406 may include the antenna radiating element 408 which may be a rectangular patch. The package size may be determined by the radiating element 408. For optimum performance, the radio frequency integrated circuit (RFIC) chip 412 may be embedded within the bottom EMC layer 410, and a package ground plane 414 may be formed between the RFIC 412 and the radiating element 408. The radiating element 408 may be connected to the RFIC 412 using a coaxial feed 418. The feed 418 may go through the package ground plane 414, and may be electrically insulated from the package ground plane 414. The package ground plane 414 may include a through hole so that the feed 418 extends through the through hole. The feed 418 may be electrically insulated from the package ground plane 414 by the EMC material or materials. The package ground plane 414 may be connected to the PCB ground plane 404 (part of the PCB 402) using the electrical via 420 and solder ball 422a. The PCB ground plane 404 (of PCB 402) below the package 406 may have an opening which allows the electrical input/output (I/O) 424 of the package 406 to be connected to the PCB signal layer 426 (of PCB 402), e.g. via solder ball 422b.

FIG. 4B is a schematic showing a three-dimensional perspective view of a simulated model of the antenna system 400 shown in FIG. 4A according to various embodiments. FIG. 4C is a schematic showing a cross-sectional side view of the simulated model of the antenna system 400 shown in FIG. 4A according to various embodiments. The hybrid AiP model shown in FIGS. 4B-C is used for antenna performance at 28 GHz simulation. For simplicity the electrical via and the solder ball are modelled as a united cylinder as shown in FIG. 4B—C. An opening is made on the PCB ground below the package. A coaxial feed with its position optimized is arranged so that the patch radiates at the designed 28 GHz frequency. The size of the rectangular patch is 3.61 mm×2.86 mm, which is also the package size. The overall height of the package without the solder ball is 0.25 mm.

The size of the PCB ground plane is varied in the simulation to analyse the effect. As the design of the Hybrid AiP includes the flip chip assembly, the solder ball height is expected to also be changed. The simulation also shows the effects of different solder ball heights.

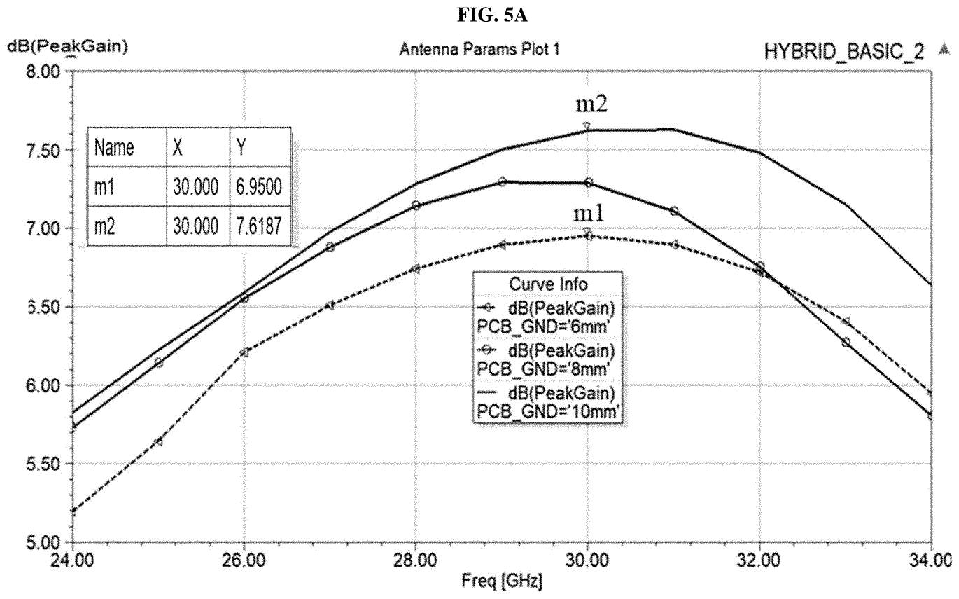

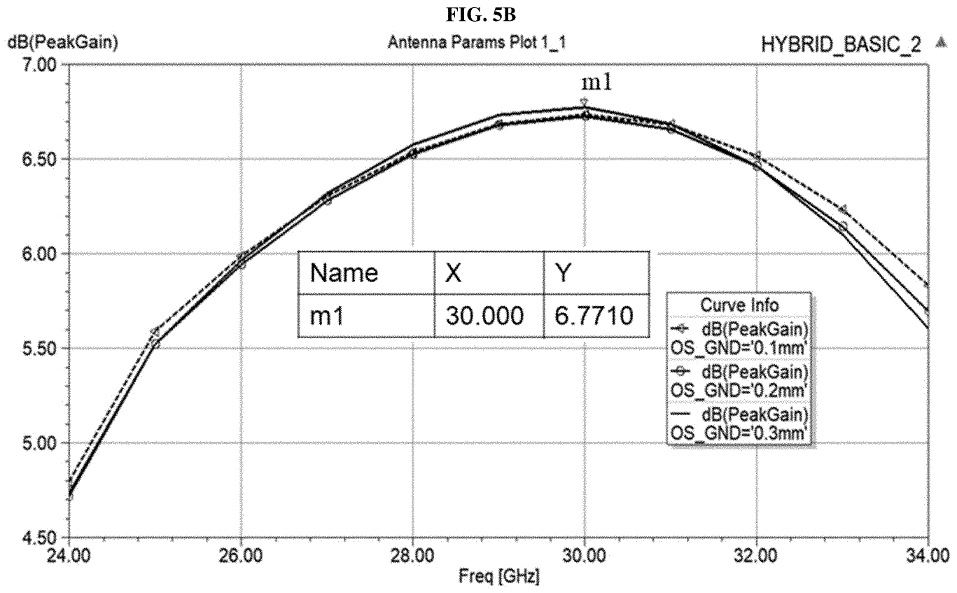

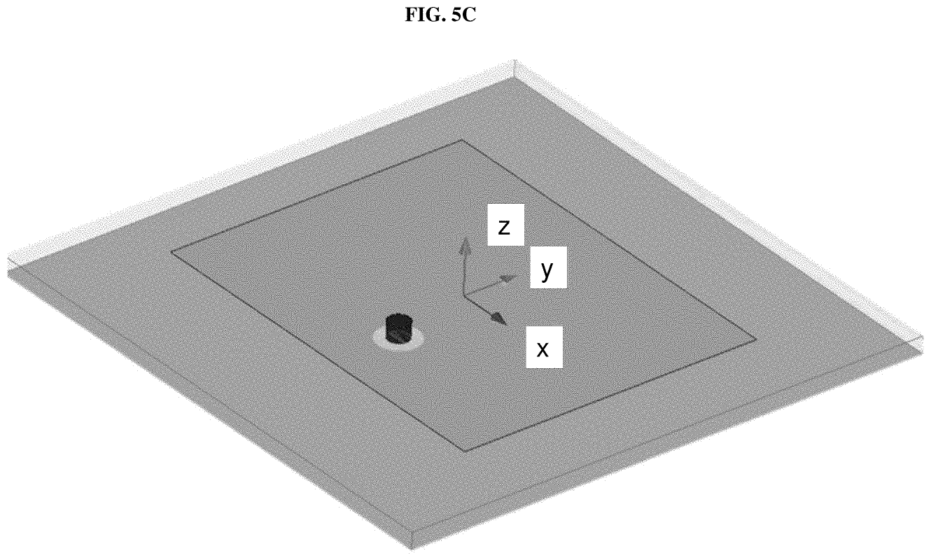

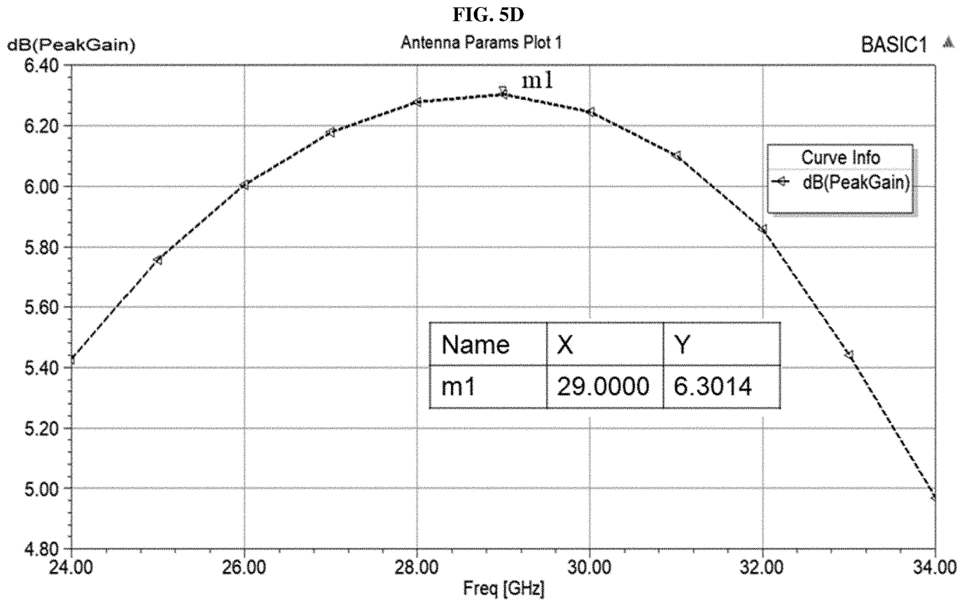

FIG. 5A is a plot of peak gain (in decibels or dB) as a function of frequency (in gigahertz or GHz) illustrating the effects of varying the size of the printed circuit board (PCB) ground on the antenna gain according to various embodiments. The results show that the antenna gain increases by increasing the PCB ground plane size.

FIG. 5B is a plot of peak gain (in decibels or dB) as a function of frequency (in gigahertz or GHz) illustrating the effects of varying the height of the solder balls on the antenna gain according to various embodiments. The results show that there is insignificant variation of the antenna gain caused by solder ball height.

FIG. 5C is a schematic showing a three-dimensional perspective view of a simulated model of a conventional antenna system. FIG. 5D is a plot of peak gain (in decibels or dB) as a function of frequency (in gigahertz or GHz) illustrating the antenna gain of the conventional antenna system as shown in FIG. 5C.

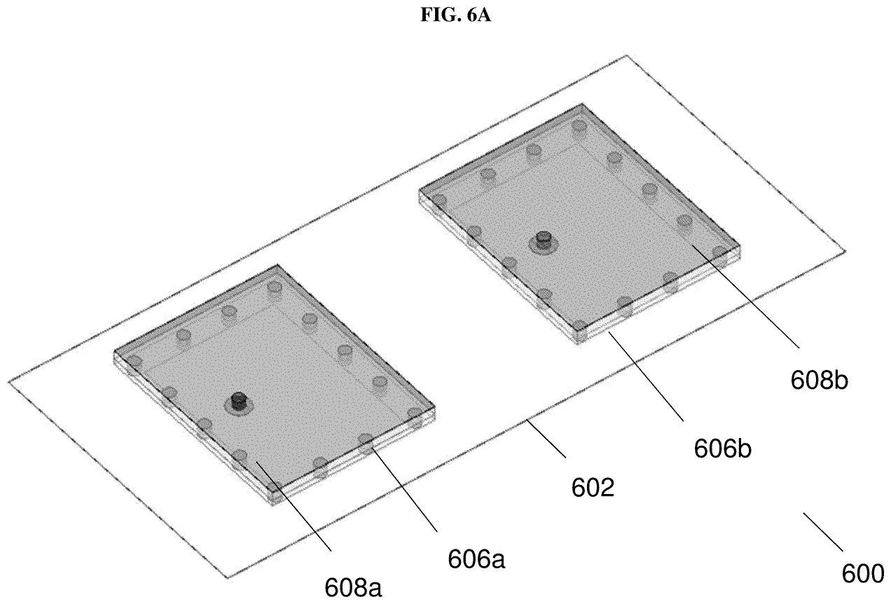

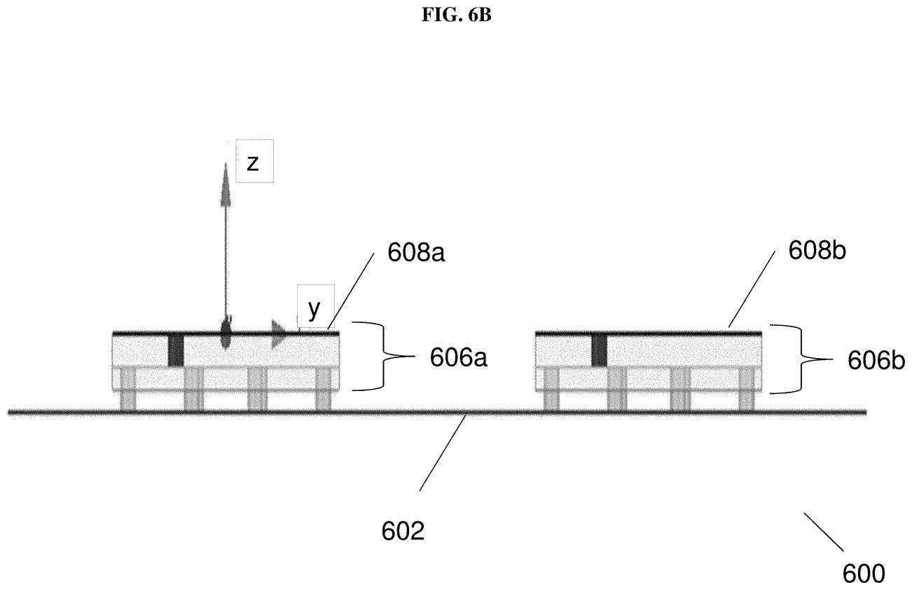

FIG. 6A is a schematic showing a three-dimensional perspective view of an antenna array 600 including two packages 606a-b and two radiating elements 608a-b over a common printed circuit board (PCB) 602 according to various embodiments. FIG. 6B is a schematic showing a cross-sectional side view of the antenna array 600 shown in FIG. 6A according to various embodiments. The antenna array 600a may form a one-dimensional (1D) phase array antenna. A scalable antenna array including multiple radiating element packages may be designed over the PCB to increase the antenna performance.

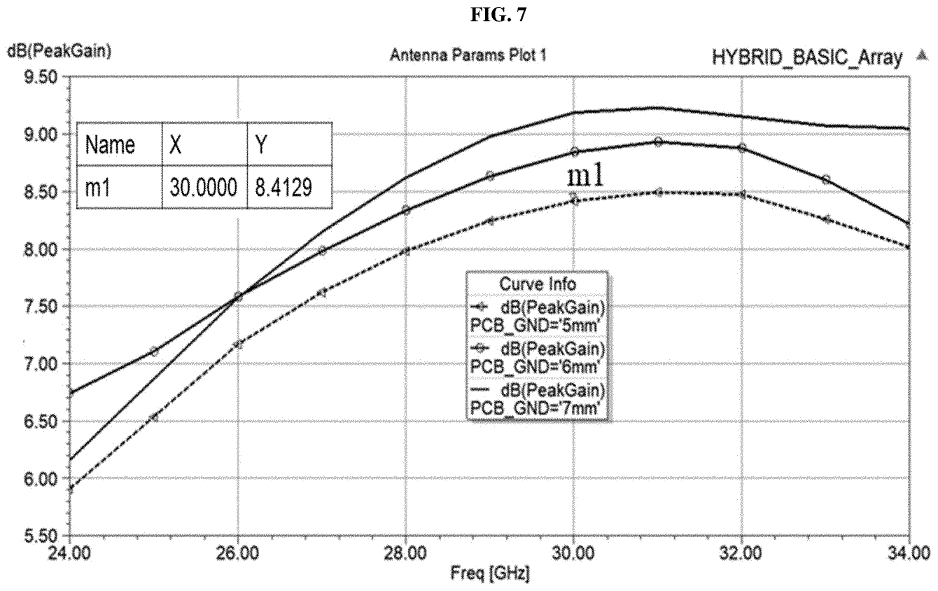

FIG. 7 is a plot of peak gain (in decibels or dB) as a function of frequency (in gigahertz or GHz) showing the electrical performance of the antenna array 600 shown in FIGS. 6A-B according to various embodiments. FIG. 7 shows that the gain of the array 600 is improved over a conventional phase antenna. The increase of the PCB ground plane may thus help to increase the antenna gain.

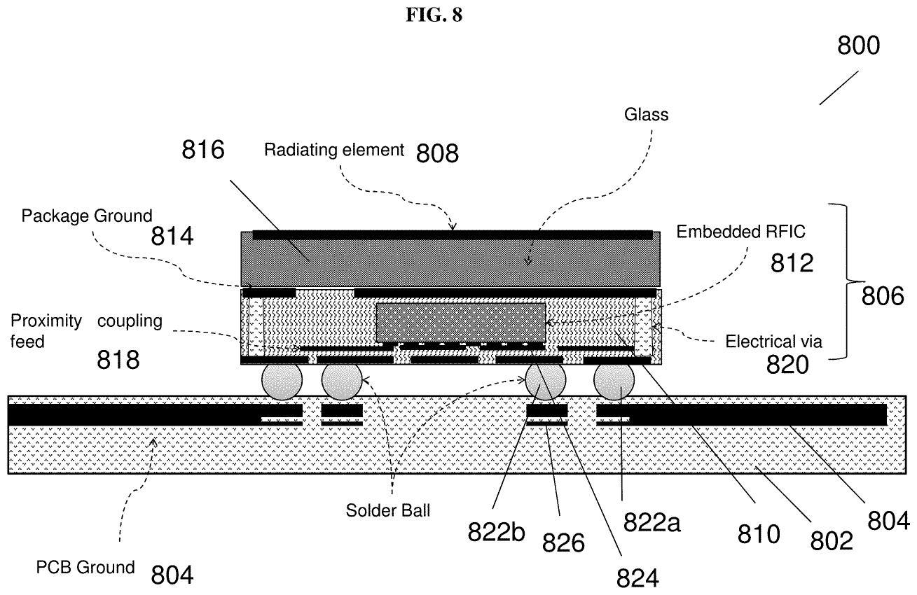

FIG. 8 is a schematic showing a cross-sectional view of an antenna system 800 according to various embodiments. The antenna system 800 may include a printed circuit board (PCB) 802 including a circuit board ground element 804. The antenna system 800 may also include a package 806 over a surface of the printed circuit board 802. The antenna system 800 may further include a radiating element 808 lying along a first plane parallel to the surface of the printed circuit board 802. The package 806 may include a first encapsulation portion 810. The package 806 may also include a radio frequency integrated circuit chip 812 embedded in the first encapsulation portion 810 including a material such as mold compound. The radio frequency integrated circuit chip 812 may lie along a second plane parallel to the surface of the printed circuit board 802. The package 806 may additionally include a package ground element 814 over the first encapsulation portion 810 and in electrical connection with the circuit board ground element 804, the package ground element 814 lying along a third plane parallel to the surface of the printed circuit board 802. The package 806 may also include a second encapsulation portion 816 such that the second encapsulation portion is between the package ground element 814 and the radiating element 808. The second encapsulation portion 816 may include a high thermal conductivity material such as glass or a material that is compatible with the fanout wafer level packaging (FOWLP) process. Instead of debonding and removing the glass wafer, the glass wafer may be thinned down to the required thickness and spluttered a metal layer to form the radiating element 808. The FOWLP wafer may then be diced with the glass wafer 816 to form the radiating module 800. The glass wafer may provide low loss substrate for the antenna system 800 and may have better thermal conductivity than the normal EMC material.

The antenna system 800 may also have a proximity coupling feed 818 having a first end coupled to the chip 812. A second end of the proximity coupling feed 818 may be aperture or slot coupled through the package ground element 814 to the radiating element 808.

The package 806 may also include one or more ground electrical vias 820 electrically connecting the circuit board ground element 804 and the package ground element 814. Solder balls 822a may couple the one or more ground electrical vias 820 to the circuit board ground element 804.

The PCB 802 may also include a signal layer 826. Solder balls 822b may couple the chip 812 to the signal layer 826 (via I/O 824 of chip 812).

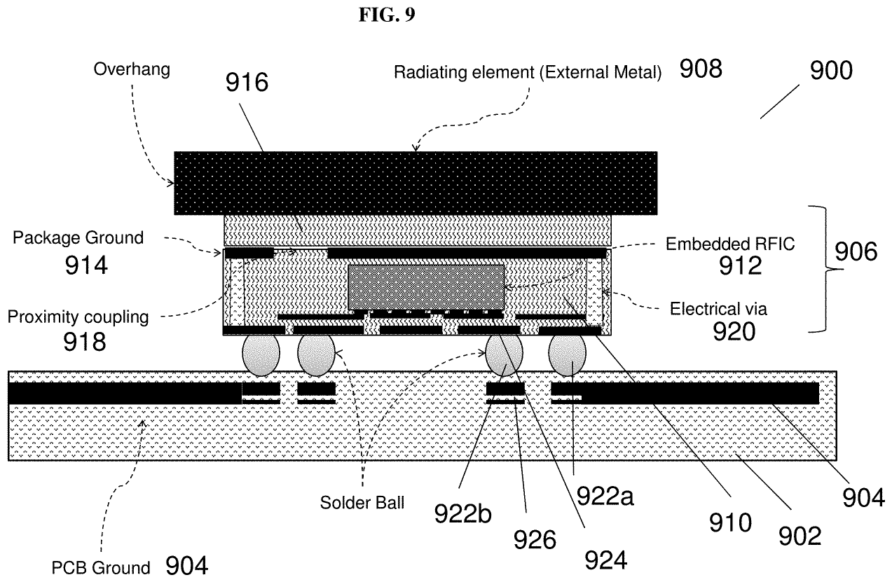

FIG. 9 is a schematic showing a cross-sectional view of an antenna system 900 according to various embodiments. The antenna system 900 may include a printed circuit board (PCB) 902 including a circuit board ground element 904. The antenna system 900 may also include a package 906 over a surface of the printed circuit board 902. The antenna system 900 may further include a radiating element 908 lying along a first plane parallel to the surface of the printed circuit board 902. The radiating element 908 may include a suitable metal. The package 906 may include a first encapsulation portion 910. The package 906 may also include a radio frequency integrated circuit chip 912 embedded in the first encapsulation portion 910. The radio frequency integrated circuit chip 912 may lie along a second plane parallel to the surface of the printed circuit board 902. The package 906 may additionally include a package ground element 914 over the first encapsulation portion 910 and in electrical connection with the circuit board ground element 904, the package ground element 914 lying along a third plane parallel to the surface of the printed circuit board 902. The package 906 may also include a second encapsulation portion 916 such that the second encapsulation portion is between the package ground element 914 and the radiating element 908.

The package 906 may be fabricated without a radiating element. The radiating element 908 may then be assembled over the package 906. The metal radiating element 908 may also be thick and may also be used a heat spreader. The radiating element 908 may be assembled such that it has an overhang. The radiating fringing field at the edge may pass through air instead of substrate. This may help to increase the radiating efficiency.

The top portion of the radiating element 908 may have fins to help to act as a heat sink and dissipate heat from the antenna system 900. The pitch between neighbouring fins may be much smaller than the antenna operating wavelength.

The antenna system 900 may also have a proximity coupling feed 918 having a first end coupled to the chip 912. A second end of the proximity coupling feed 918 may be aperture or slot coupled through the package ground element 914 to the radiating element 908.

The package 906 may also include one or more ground electrical vias 920 electrically connecting the circuit board ground element 904 and the package ground element 914. Solder balls 922a may couple the one or more ground electrical vias 920 to the circuit board ground element 904.

The PCB 902 may also include a signal layer 926. Solder balls 922b may couple the chip 912 to the signal layer 926 (via I/O 924 of chip 912).

This design may be suitable for high power application where the package height is not critical.

Various embodiments may relate to a hybrid AiP design including the radiating module with the RFIC embedded inside. The main ground plane may be formed in the PCB. The gain of the antenna may be increased by increasing the PCB ground plane without increasing the radiating module package size.

The radiating element of the antenna may be designed on the top of embedded RFIC, this formed the radiating module. The size of the radiating module may be sufficient just to accommodate the radiating element.

A ground plane may be designed between the top radiating element and the bottom RFIC inside the Radiating Module.

The RFIC may be embedded face down.

The radiating module ground plane may be connected to the PCB ground plane through vias and solder balls. These connections may be formed around the edge of radiating module. The PCB ground plane may be extended outward to improve the antenna performance.

The PCB ground plane may be extended beneath the radiating module for the solder ball connection.

An opening may be designed on the PCB ground plane beneath the radiating module. The opening is for other electrical connections.

Multiple radiating modules may be designed on the same PCB ground plane. This may form an array antenna.

The radiating element may be formed on the top layer. The top layer may be fabricated using different material such as glass.

The conducting radiating element layer can be assembled on the module instead of fabricated using the FOWLP process. The pattern metal layer which formed the radiating element may be designed such that it is overhang.

Various embodiments may reduce the package size. Various embodiments may improve AiP package.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An antenna system comprising:
a printed circuit board comprising a circuit board ground element;
a package over a surface of the printed circuit board; and
a radiating element lying along a first plane parallel to the surface of the printed circuit board;
wherein the package comprises:
a first encapsulation portion;
a radio frequency integrated circuit chip embedded in the first encapsulation portion, the radio frequency integrated circuit chip lying along a second plane parallel to the surface of the printed circuit board;
a package ground element over the first encapsulation portion and in electrical connection with the circuit board ground element, the package ground element lying along a third plane parallel to the surface of the printed circuit board; and
a second encapsulation portion such that the second encapsulation portion is between the package ground element and the radiating element;
wherein an area of the radiating element along the first plane is greater than an area of the package ground element along the third plane;
wherein the area of the radiating element along the first plane is also greater than an area of the radio frequency chip along the second plane; and
wherein the third plane is between the first plane and the second plane.

2. The antenna system according to claim 1,
wherein the radiating element is configured to emit radio frequency signals in a direction away from the printed circuit board.

3. The antenna system according to claim 1,
wherein the package is mounted to the surface of the printed circuit board; and
wherein the circuit board ground element extends from the surface of the printed circuit board.

4. The antenna system according to claim 1,
wherein the radio frequency integrated circuit chip has an active surface facing the printed circuit board.

5. The antenna system according to claim 1,
wherein the package is devoid of circuits in a space extending from the radiating element to the printed circuit board.

6. The antenna system according to claim 1,
wherein the first encapsulation portion comprises a mold compound; and
wherein the second encapsulation portion also comprises the mold compound.

7. The antenna system according to claim 1,
wherein the first encapsulation portion comprises a mold compound; and
wherein the second encapsulation portion comprises a thermal conductive material.

8. The antenna system according to claim 7,
wherein the thermal conductive material is glass.

9. The antenna system according to claim 1,
wherein the radiating element is comprised in the package.

10. The antenna system according to claim 1,
wherein the radiating element extends beyond the package.

11. The antenna system according to claim 10,
wherein the radiating element comprises a plurality of fins.

12. The antenna system according to claim 1,
wherein the package further comprises one or more signal electrical vias electrically connecting the radiating element and the radio frequency integrated circuit chip.

13. The antenna system according to claim 1,
wherein the package also includes one or more ground electrical vias electrically connecting the circuit board ground element and the package ground element.

14. The antenna system according to claim 13,
wherein the one or more ground electrical vias surround the radio frequency integrated circuit chip.

15. The antenna system according to claim 1,
wherein the printed circuit board further comprises a circuit board signal element in electrical connection with the radio frequency integrated circuit chip.

16. A method of forming an antenna system, the method comprising:
forming a package over a surface of a printed circuit board, the printed circuit board comprising a circuit board ground element;
forming a radiating element lying along a first plane parallel to the surface of the printed circuit board;
wherein the package comprises:
a first encapsulation portion;
a radio frequency integrated circuit chip embedded in the first encapsulation portion, the radio frequency integrated circuit chip lying along a second plane parallel to the surface of the printed circuit board;
a package ground element over the first encapsulation portion and in electrical connection with the circuit board ground element, the package ground element lying along a third plane parallel to the surface of the printed circuit board; and
a second encapsulation portion such that the second encapsulation portion is between the package ground element and the radiating element;
wherein an area of the radiating element along the first plane is greater than an area of the package ground element along the third plane;
wherein the area of the radiating element along the first plane is also greater than an area of the radio frequency chip along the second plane; and
wherein the third plane is between the first plane and the second plane.

17. The method according to claim 16,
wherein the first encapsulation portion includes a mold compound; and
wherein the second encapsulation portion also includes the mold compound.

18. The method according to claim 16,
wherein the first encapsulation portion includes a mold compound; and
wherein the second encapsulation portion includes a thermal conductive material.

19. The method according to claim 16,
wherein the radiating element is comprised in the package.

20. The method according to claim 16,
wherein the radiating element extends beyond the package.
